(19) United States
(12) Patent Application Publication
(10) Pub. No.: US 2010/0188536 A1
(43) Pub. Date: Jul. 29, 2010

(54) SOLID-STATE IMAGING ELEMENT, SOLID-STATE IMAGING DEVICE, CAMERA, AND DRIVE METHOD

(75) Inventors: Tsuyoshi Hasuka, Osaka (JP); Toshihiro Kuriyama, Shiga (JP); Hiroyuki Mori, Osaka (JP); Junji Manabe, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/670,040

(22) PCT Filed: Jul. 9, 2008
(86) PCT No.: PCT/JP2008/001834

§ 371 Date: Jan. 21, 2010

(30) Foreign Application Priority Data
Jul. 31, 2007 (JP) 2007-199628

(51) Int. Cl. H04N 5/335; H01L 27/148; H01L 31/101

(52) U.S. Cl. 348/294; 250/208.1; 250/214 SW; 348/E05.091

(57) ABSTRACT

The semiconductor element according to an aspect of the present invention is a solid-state imaging element formed on a semiconductor substrate, having an overflow drain structure for draining excessive charges generated in photoelectric conversion elements, and reading out signal charges accumulated in the photoelectric conversion elements to a vertical transfer unit via a readout gate electrode. The solid-state imaging element includes: a first voltage generating circuit which applies, to the semiconductor substrate, substrate voltage defining the height of overflow barrier in the overflow drain structure; and a second voltage generating circuit which selectively generates first voltage and second voltage each including the height of pulse wave superimposed onto the substrate voltage, at a time when readout pulse to be applied to the readout gate electrode is generated.

### TECHNICAL FIELD

The present invention relates to a solid-state imaging element, a solid-state imaging device, and a camera in which signal charges accumulated in photoelectric conversion units arranged in a matrix pattern are read out for obtaining two-dimensional image signals, and to a drive method thereof.

### BACKGROUND ART

A solid-state imaging device forms an imaging unit of a camcorder or a digital camera, or an image recognition unit of a fax machine or an image scanner. A charge coupled device (CCD) image sensor has been widely used as an imaging element.

FIG. 1 is a block diagram showing a structure of a conventional solid-state imaging device disclosed, for example, in patent reference 1. A solid-state imaging device 275 has an overflow drain structure for draining excess charges generated in photoelectric conversion elements 201. In the overflow drain structure, substrate voltage Vsub applied from a reference voltage generating circuit 209 to a semiconductor substrate 207 forms an overflow barrier between the photoelectric conversion elements 201 and the backside of the semiconductor substrate 207. Since the height of the overflow barrier can be adjusted according to the value of the substrate voltage Vsub, the overflow drain structure is also used for an electronic shutter in which all signal charges in all photoelectric conversion elements are drained, and for blooming suppression.

Here, a conventional method for suppressing blooming is described with reference to FIG. 2.

As shown in FIG. 2, during the period in which signal charge is transferred setting a transfer gate region 24 to the potential indicated by dashed line, the charge generated in a photodiode 1 is accumulated in a vertical CCD channel 2a, the transfer gate region 24, and the photodiode 1, until potential 25b of the accumulated charge reaches the potential lower than the potential 26a of p well region 17.

However, when the potential of the barrier on neighboring regions in the vertical CCD channel 2a is higher than the potential 26a, the charge starts to overflow into the neighboring regions in the vertical CCD channel 2a before the excess charge starts to overflow to a n-type substrate. More specifically, during the period in which signal charge is transferred from the photodiode 1, blooming suppression does not actually work.

In order to make blooming suppression work also during the charge transfer period, patent reference 2 describes a structure in which different substrate voltage Vsub is applied to the n-type substrate during the charge accumulation period in which charge is accumulated in the photodiode and during the charge transfer period. The charge transfer period is a period during which signal charge is read out from the photoelectric conversion element to the vertical CCD.

More specifically, in the technique disclosed by patent reference 2, the p well region 17 is set to the low-level potential 26a, which is the same as in the conventional methods, during most of the signal charge accumulation period, and is set to the high-level potential 26b during the charge transfer period.

With this, during the charge transfer period, the charge, having the potential shallower (lower) than the potential 26b at which excess charge is drained, is drained to the n-type substrate without being accumulated in the photodiode 1. As a result, blooming is suppressed, making the potential of the barrier on the neighboring regions in the vertical CCD 2 lower than the potential 26b.

Further, patent reference 3 describes a circuit which switches, using a switching unit SW, substrate voltage for different charge accumulation modes that are field accumulation and frame accumulation.

### Patent Reference 1: Japanese Unexamined Patent Application Publication No. 7-284026

### Patent Reference 2: Japanese Unexamined Patent Application Publication No. 61-26375

Patent reference 3: Japanese Unexamined Patent Application Publication No. 5-211320

### DISCLOSURE OF INVENTION

### Problems that Invention is to Solve

For example, a CCD with a large number of pixels, used for a digital camera, includes following modes: an all-pixel mode (for example, a still image mode) in which accumulated charges of all pixels are individually detected to create image data; a high frame rate mode (for example, a monitor mode and a moving image mode) in which information is added while lines are thinned to reduce information amount and increase frame rate for obtaining moving image data; and a high sensitivity mode in which pixels are mixed for obtaining still image and moving image data with increased sensitivity.

In the high frame rate mode and the high sensitivity mode, signal charges of same color pixels that are read out to the same vertical CCD are transferred to a charge detecting unit after a predetermined number of the signal charges are mixed (hereinafter referred to as pixel mixture). Accordingly, image signals for a single row are generated at a predetermined interval in a vertical direction.

In the pixel mixture, charges of plural pixels are mixed, which results in increasing the amount of the added charges. Therefore, in order not to exceed transfer capability of the vertical CCD or horizontal CCD, it is required to limit the amount of charge to be transferred.

Thus, for the driving mode in which pixels are mixed, such control is required that the substrate voltage Vsub is increased depending on the number of pixels to be mixed so as to limit charge accumulated in the photodiode, and to keep the amount of the added charges within a range which does not affect the transfer. Coupled with miniaturization and downsizing of photoelectric conversion elements in recent years, the amount of saturation signal charge of the photoelectric conversion elements and the capacity of the transfer of the vertical CCD and horizontal CCD are also decreased. As a result, control of the amount of the charge by the substrate voltage is becoming difficult, and high precision control is required. Since adverse effects induced by manufacturing variability of individual solid-state imaging element increase in proportion to the number of photodiodes to be mixed, such high precision control is particularly important.

Further, in the solid-state imaging device disclosed by the conventional techniques, it is not possible to precisely set Vsub for pixel mixture. Therefore, high-speed mode switching in a digital camera, among, for example, a still-image mode, monitor mode, and high sensitivity mode, is not possible, which results in deteriorating responsive properties of the digital camera.

In view of the stated problems, the present invention has an object to provide a solid-state imaging element, a solid-state imaging device and a camera in which substrate voltage can be controlled according to modes with different number of pixels to be mixed, and a drive method of the solid-state imaging device.

Further, another object is to provide a solid-state imaging element, a solid-state imaging device, and a camera, in which manufacturing variability of individual solid-state imaging element is absorbed, substrate voltage is precisely controlled, and the substrate voltage is switched at high speed, and a drive method of the solid-state imaging device.

### Means to Solve the Problems

The solid-state imaging element which solves the above problems is a solid-state imaging element formed on a semiconductor substrate, having an overflow drain structure for draining excess charges generated in photoelectric conversion elements, and reading out signal charges accumulated in the photoelectric conversion elements to a vertical transfer unit via a readout gate electrode. The solid-state imaging element includes: a first voltage generating circuit which applies a substrate voltage to the semiconductor substrate, the substrate voltage defining a height of an overflow barrier in the overflow drain structure; and a second voltage generating circuit which selectively generates a first voltage and a second voltage at a time when a readout pulse to be applied to the readout gate electrode is generated, the first voltage and the second voltage each indicating a height of a pulse wave superimposed onto the substrate voltage.

With this structure, when the signal charge accumulated in the photoelectric conversion element is read out to the vertical transfer unit via the readout gate electrode, the pulse of the first voltage or the second voltage is superimposed onto the substrate voltage. Since the amount of the saturation signal charge of the photoelectric conversion element is adjusted according to each of the first voltage and the second voltage, it is possible not only to suppress blooming which occurs at the time of reading out, but also to control the substrate voltage according to different imaging modes.

Here, it may be that the second voltage generating circuit generates the first voltage in a first mixing mode in which signal charges of N photoelectric conversion elements are mixed in the vertical transfer unit, and generates the second voltage higher than the first voltage in a second mixing mode in which signal charges of M photoelectric conversion elements are mixed, M being greater than N.

With this structure, in each of the first mixing mode and the second mixing mode, it is possible to precisely limit the amount of saturation signal charge accumulated in the photodiode such that the amount of the mixed charges is in the range which does not cause overflow in the vertical transfer unit and the horizontal transfer unit.

Here, it may be that the second voltage generating circuit includes: a resistive circuit which includes resistive elements connected in series, and outputs the first voltage and the second voltage by a voltage division; and a switch circuit which includes an input terminal to which a switch signal indicating the first voltage or the second voltage is inputted, and switches an output of the resistive circuit between the first voltage and the second voltage according to the switch signal.

With this structure, the second voltage generating circuit can be structured simply, and switching according to the switching signal is possible.

Here, it may be that the switch signal is switched immediately after the readout pulse is generated in a field period or a frame period, each of the field period and the frame period being a period immediately before switching into the first mixing mode or the second mixing mode.

With this structure, switching of the switch signal is performed earlier than switching into the first mixing mode or the second mixing mode. Thus, at the time when readout pulse is generated in the period of the first mixing mode or the second mixing mode, the first voltage or the second voltage outputted from the second voltage generating circuit is inputted to the drive unit at a steady level without being influenced by stray capacitance of wiring. As a result, in synchronization with switching into the first mixing mode or the second mixing mode, high-speed switching of substrate voltage is possible.

Here, it may be that the switch circuit includes a switch transistor which is connected in parallel with a first resistive element among the resistive elements, and the switch transistor includes a gate connected to the input terminal.

With this structure, the switch circuit can be made of a simple circuit which controls whether or not the first resistive element is short-circuited by the switch transistor.

Here, it may be that the second voltage generating circuit further includes a constant current source connected in series with the resistive elements.

With this structure, the constant current source maintains constant current flowing through the resistive elements; and thus, it is possible to improve precision of the first voltage and the second voltage.

Here, it may be that the second voltage generating circuit further includes a voltage buffer circuit which drives the first voltage or the second voltage outputted from the resistive circuit.

With this structure, the output level of the second voltage generating circuit can be increased to the steady level of the first voltage or the second voltage more rapidly, which allows high-speed switching of substrate voltage.

Here, it may be that the switch circuit further includes at least one fuse circuit which is connected in parallel with a resistive element among the resistive elements.

With this structure, it is possible to adjust the level of the first voltage and the second voltage by blowing the fuse circuit; and thus, adverse effects of the manufacturing variability of each solid-state imaging element can be compensated, for example, at the time of factory shipment, and precise control of substrate voltage is possible.

Here, it may be that the switch circuit further includes at least two pads which receive power for blowing the fuse circuit.

With this structure, reduction in circuit area is possible since the fuse circuit is a simple circuit.

Further, the solid-state imaging device, the camera and the drive method of the solid-state imaging device that solve the above problems have the same structure as above.

### EFFECTS OF THE INVENTION

According to the solid-state imaging element, solid-state imaging device, camera, and the drive method of the solid-state imaging device according to an aspect of the present invention, not only suppressing blooming at the time of reading out, but also controlling substrate voltage according to different imaging modes are possible.

Further, the amount of saturation signal charge accumulated in photodiodes can be precisely limited.

Further, in synchronization with switching into the first mixing mode or the second mixing mode, high-speed switching of substrate voltage is possible.

Further, it is possible to compensate adverse effects of the manufacturing variability of each solid-state imaging element, for example, at the time of factory shipment; and thus, precise control of substrate voltage is possible.

### BRIEF DESCRIPTION OF DRAWINGS

FIG. 1 is a conceptual diagram showing a planar structure of a conventional solid-state imaging device.

FIG. 2 is a diagram showing the distribution of potential in various parts around the photodiode.

FIG. 3 is a block diagram showing a structure of a solid-state imaging device according to a first embodiment of the present invention.

FIG. 4 is a cross-sectional view showing a structure of neighboring parts of the photodiode.

FIG. 5 is a diagram showing the distribution of potential in various parts around the photodiode shown in FIG. 3.

FIG. 6 is a waveform diagram showing pulse waveforms for driving the solid-state imaging device.

FIG. 7 is a waveform diagram showing the pulse waveforms in detail.

FIG. 8 is a circuit diagram showing an example of a first reference voltage generating circuit.

FIG. 9 is a circuit diagram showing an example of a second reference voltage generating circuit.

FIG. 10 is a waveform diagram showing pulse waveforms of the second reference voltage generating circuit.

FIG. 11 is a diagram showing a structure of the second reference voltage generating circuit according to a first variation.

FIG. 12 is a diagram showing a structure of the second reference voltage generating circuit according to a second variation.

FIG. 13 is a diagram showing a structure of the second reference voltage generating circuit according to a third variation.

FIG. 14 is a diagram showing a structure of the second reference voltage generating circuit according to a fourth variation.

FIG. 15 is a diagram showing a structure of the second reference voltage generating circuit according to a fifth variation.

FIG. 16 is a block diagram showing a structure of a solid-state imaging device according to a second embodiment of the present invention.

FIG. 17 is a circuit diagram showing an example of a second reference voltage generating circuit.

FIG. 18 is a diagram showing a structure of the second reference voltage generating circuit according to a first variation.

FIG. 19 is a diagram showing a structure of the second reference voltage generating circuit according to a second variation.

FIG. 20 is a diagram showing a structure of the second reference voltage generating circuit according to a third variation.

FIG. 21 is a diagram showing a structure of the second reference voltage generating circuit according to a fourth variation.

FIG. 22 is a diagram showing a structure of the second reference voltage generating circuit according to a fifth variation.

FIG. 23 is a diagram showing a structure of the second reference voltage generating circuit according to a sixth variation.

FIG. 24 is a diagram showing a structure of the second reference voltage generating circuit according to a seventh variation.

FIG. 25 is a diagram showing a structure of the second reference voltage generating circuit according to an eighth variation.

FIG. 26 is a diagram showing a structure of the second reference voltage generating circuit according to a ninth variation.

FIG. 27 is a diagram showing a structure of the second reference voltage generating circuit according to a tenth variation.

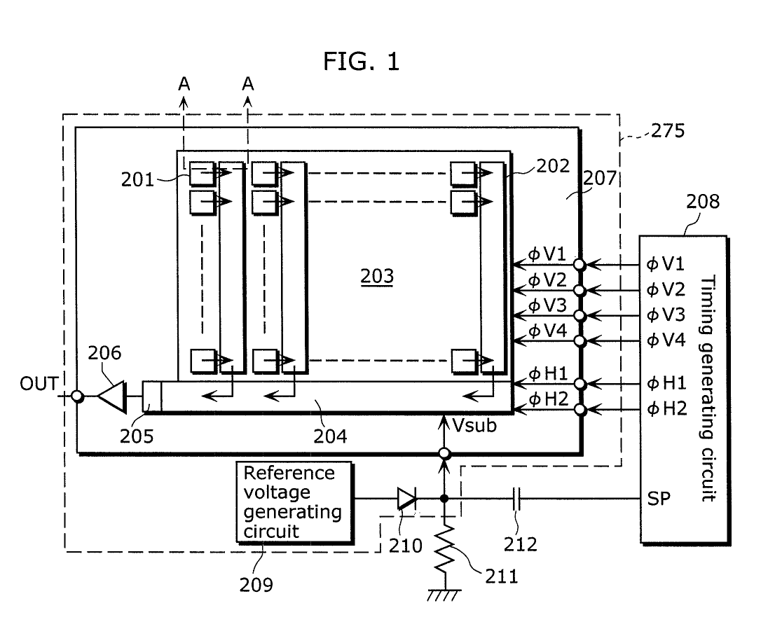

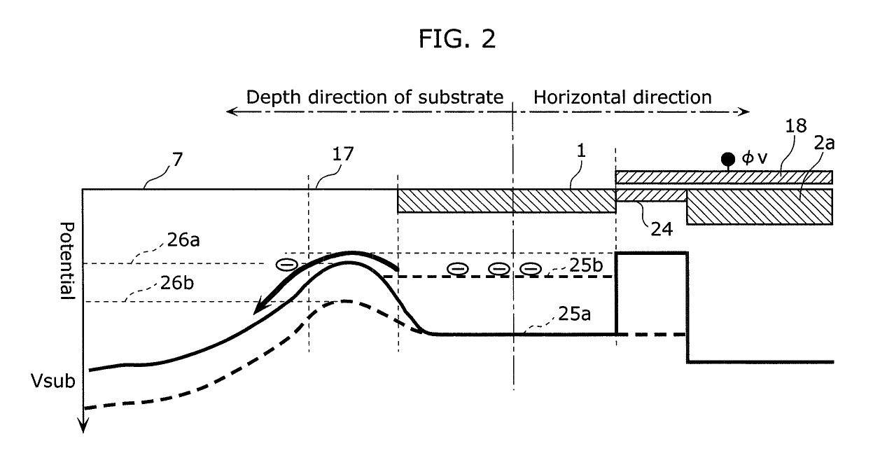

### NUMERICAL REFERENCES

1 Photodiode
2 Vertical CCD
2a Vertical CCD channel
3 Imaging region
4 Horizontal CCD
5 Charge detecting unit
6 Output amplifier
7 Solid-state imaging element
8 Drive circuit
10 Diode
11 Resistance
12 Capacitor
13 Switch circuit
14, 15, 16 Terminal
17 P well region
18 Electrode
19 Isolation region
24 Transfer gate region
50 First reference voltage generating circuit
51, 501 Second reference voltage generating circuit
70 N-type substrate
100 Reference voltage switch terminal
101 Switch transistor
102 Constant current source
103 Output transistor

### BEST MODE FOR CARRYING OUT THE INVENTION

Hereinafter, a solid-state imaging device and a drive method thereof according to embodiments of the present invention will be described with reference to the drawings.

### First Embodiment

A solid-state imaging device according to a first embodiment includes a solid-state imaging element formed on a semiconductor substrate. The solid-state imaging element includes: a first voltage generating circuit which applies, to the semiconductor substrate, substrate voltage which defines the height of overflow barrier in the overflow drain structure; and a second voltage generating circuit which selectively generates first voltage or second voltage each indicating the height of pulse wave superimposed onto the substrate voltage at a time when readout pulse applied to the readout gate electrode is generated.

The second voltage generating circuit generates the first voltage in first mixing mode in which signal charges of N photoelectric conversion elements (for example, where N is six) are mixed in the vertical transfer unit, and generates the second voltage higher than the first voltage in second mixing mode in which signal charges of M photoelectric conversion elements which are more than the N photoelectric conversion elements (for example, where M is nine) are is mixed.

With this structure, when signal charge accumulated in the photoelectric conversion element is read out to the vertical transfer unit via the readout gate electrode, the pulse of the first voltage or the second voltage is superimposed onto the substrate voltage. Since the amount of saturation signal charge of the photoelectric conversion element is adjusted according to each of the first voltage and the second voltage, it is possible not only to suppress blooming at the time of reading out, but also to control substrate voltage according to different imaging modes. Further, with this structure, in each of the first mixing mode and the second mixing mode, it is possible to precisely control the amount of saturation signal charge accumulated in photodiode such that the amount of the mixed charges is in the range which does not cause overflow in the vertical transfer unit and the horizontal transfer unit.

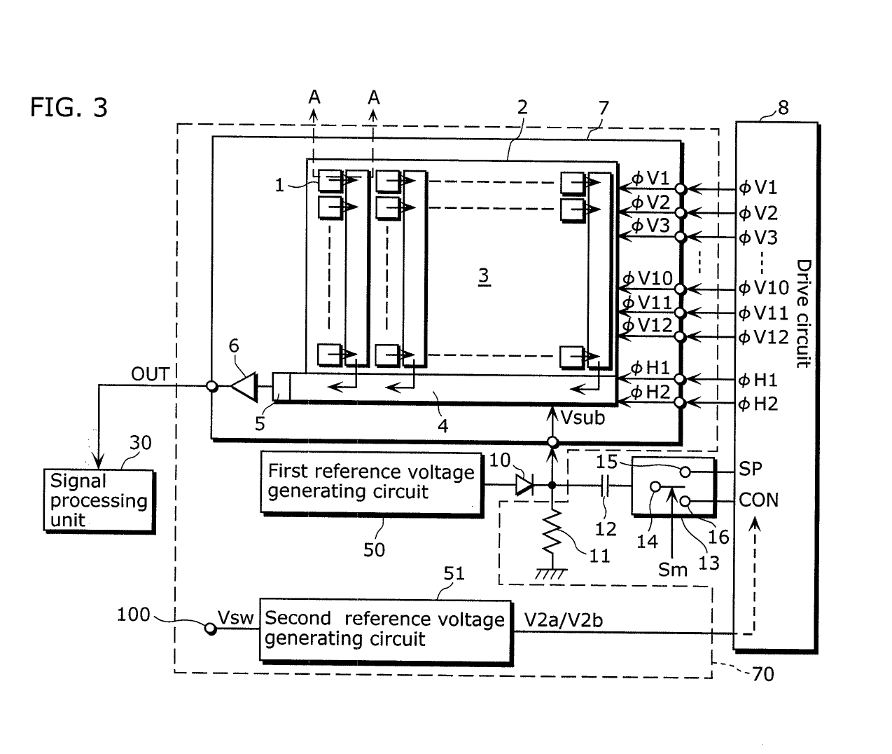

FIG. 3 is a block diagram showing a structure of the solid-state imaging device according to the present embodiment.

As seen in FIG. 3, 1 represents a photodiode which forms the photoelectric conversion unit, and a plurality of photodiodes are arranged in a matrix pattern. Each vertical CCD 2 is arranged between the columns of the photodiodes, forming an imaging region 3.

The charge accumulated in each photodiode 1 is transferred to the respective vertical CCDs 2, and then transferred in parallel from the respective vertical CCDs 2 to a horizontal CCD 4. Therefore, signal charges for a single scanning line are sequentially transferred from a plurality of vertical CCDs 2 to the horizontal CCD 4.

The charges reached to the horizontal CCD 4 are horizontally transferred and converted into signal voltage by a charge detecting unit 5. After being amplified by an output amplifier 6, the amplified signal voltage is outputted as an image output OUT. The solid-state imaging element 7 including the above elements are formed on a n-type substrate 70.

Then, a signal processing unit 30 processes signals for outputting an image.

The vertical CCD 2 is driven to transfer by, for example, twelve-phase transfer clock φV1, φV2 to φV12 provided from a drive circuit 8.

With this, signal charges for each single scanning line that are read out to the vertical CCDs 2 are transferred in a vertical direction in a horizontal blanking period.

The horizontal CCD 4 is driven to transfer by, for example, two-phase horizontal transfer clock φH1 and φH2. With this, signal charges for a single scanning line are sequentially transferred in a horizontal direction in a horizontal scanning period that is after the horizontal blanking period.

The n-type substrate 70 is grounded via a resistance 11. A first reference voltage generating circuit 50 is connected to the connection point between the n-type substrate 70 and the resistance 11 via a diode 40.

The reference voltage generated by the first reference voltage generating circuit 50 is applied to the n-type substrate 70 as substrate voltage Vsub.

As described later, the substrate voltage Vsub is a voltage applied to determine the saturation amount of signal charge accumulated in photodiode 1.

In consideration of variability of height of potential barrier formed by the substrate voltage Vsub, which is generated along with manufacturing variability of CCD imaging sensor, the reference voltage is set to an optimum value for each element (chip).

On the other hand, in the CCD imaging sensor which can perform an electronic shutter operation, shutter pulse SP is generated in the drive circuit 8, and the shutter pulse SP is applied to the n-type substrate 70 after direct-current component of the shutter pulse SP is eliminated by the capacitor 12.

At this time, the low-level of the shutter pulse SP is clamped to the DC level of the reference voltage by the diode 10 (See Patent Reference 1, for example).

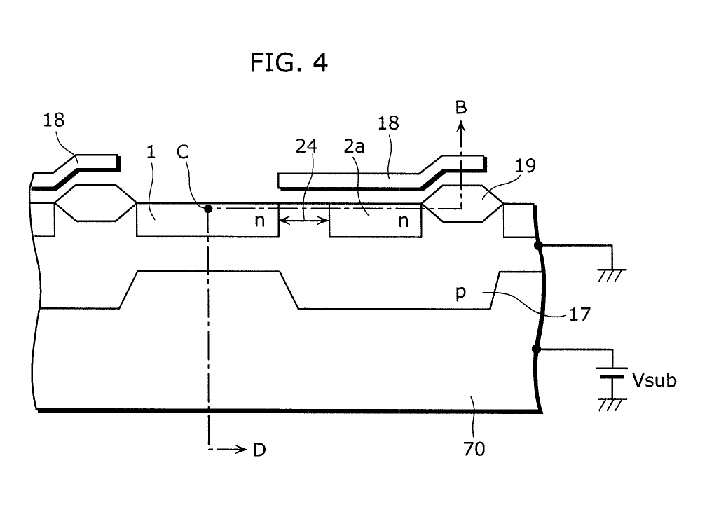

Next, the structure of elements of the solid-state imaging device according to an embodiment of the present invention is described with reference to FIG. 4. Note that FIG. 4 is a cross sectional view of elements of line A-A of FIG. 3.

Firstly, as seen in FIG. 4, a p well region 17 is formed in the upper part of the n-type substrate 70. In the p well region 17, the photodiode 1 and the vertical CCD channel 2a are formed.

Electrodes 18, which serve as transfer electrodes of the vertical CCD and also as electrodes for controlling the transfer of signal charge from the photodiode 1, are formed above the p well region 17.

Further, 19 represents isolation region. The solid-state imaging element having this structure is driven by pulses of three different values. When the highest voltage is applied, signal charge is transferred from the photodiode 1 to the vertical CCD channel 2a through a transfer gate region 24. More specifically, the charge is read out from the photodiode 1 to the vertical CCD 2.

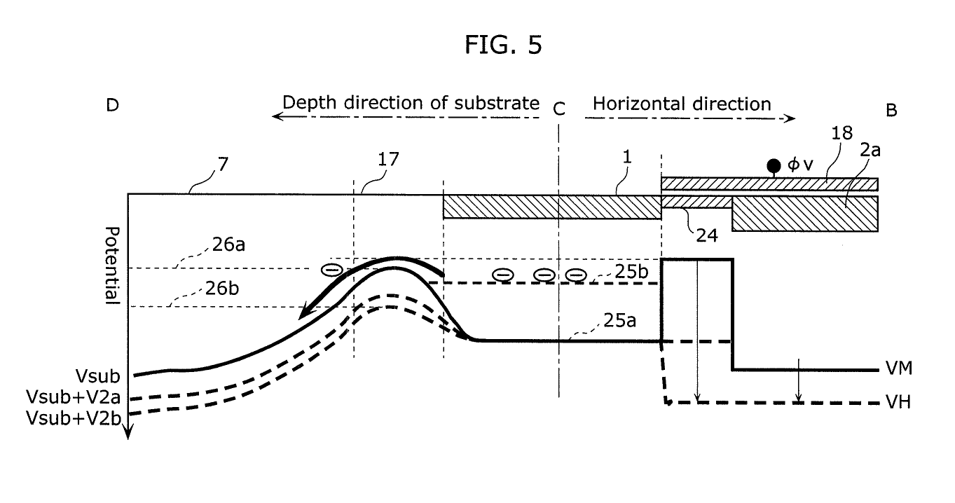

FIG. 5 is a diagram showing the potential distribution of neighboring parts of the photodiode 1 of the solid-state imaging device according to an embodiment of the present invention. Operation for blooming suppression in this solid-state imaging element is described with reference to FIG. 5 showing potential distribution of line B-C-D of FIG. 4. Respective regions in FIG. 5 are represented by the same numerical references of the corresponding photodiode 1, the transfer gate region 24, the vertical CCD channel 2a, the p well region 17, and the n-type substrate 70.

As seen in FIG. 5, since the substrate voltage Vsub is applied between the p well region 17 and the n-type substrate 70, the part of the p well region 17 which is under the pn junction photodiode 1 is depleted, and potential barrier is formed in the potential distribution indicated by the solid line.

Further, the potential of the transfer gate region 24 indicated by the solid line represents a state in which signal charge is not transferred. When signal charge is transferred, the potential becomes the level indicated by the dashed line.

When the transfer gate region 24 reaches the potential indicated by the dashed line, charge of the photodiode 1 is transferred to the vertical CCD channel 2a, resulting in making the photodiode 1 an empty state as indicated by the potential 25a.

When the accumulation period starts after the transfer period, well of the potential of the photodiode 1 becomes shallower as indicated by the potential 25b as charge of incident light is accumulated.

When the potential 25b becomes lower than the potential 26a of the p well region 17 in the potential distribution indicated by the solid line, excess charge is drained to the n-type substrate 70 through the p well region 17.

In such a manner, when charge is accumulated in the photodiode 1 exceeding the amount of the saturation charge determined by the potential barrier of the p well region 17, excess charge is drained to the n-type substrate 70, thereby suppressing blooming.

When the substrate voltage Vsub is increased, the potential distribution becomes a state indicated by the dashed line, and the amount of the saturation charge indicated by the potential 26b of the p well region 17 is set to a lower value.

In the present embodiment, the substrate voltage can be switched to a high-level reference voltage of Vsub+V2a or Vsub+V2b in the charge transfer period. Accordingly, by setting an appropriate substrate voltage Vsub, blooming suppression suitable for property of the solid-state imaging element can be obtained.

Further, the solid-state imaging device according to the present embodiment includes, as a driving mode, an all-pixel mode, high-frame mode, and a high-sensitivity mode. In order to control the amount of the saturation charge in the photodiode 1 by applying different substrate voltage Vsub to the n-type substrate 70 depending on the driving mode, a switch circuit 13 is connected between the drive circuit 8 and the capacitor 12.

The drive circuit 8 supplies, as pulse voltage to be applied to the n-type substrate 70, control pulse CON in addition to shutter pulse SP.

More specifically, the control pulse CON is a pulse corresponding to high-level reference voltage in the charge transfer period in the pixel mixture mode, and is superimposed onto the substrate voltage Vsub via the switch circuit 13 and the capacitor 12. The drive circuit 8 outputs the control pulse CON after connecting the switch circuit 13 to the terminal 16.

The solid-state imaging device includes the first reference voltage generating circuit 50 and the second reference voltage generating circuit 51.

The voltage value of the control pulse CON is determined by the output signal of the second reference voltage generating circuit 51. The output signal of the second reference voltage generating circuit 51 is outputted to the drive circuit 8 as a reference signal, and one of the first voltage V2a and the second voltage V2b is outputted.

The second reference voltage generating circuit 51 generates reference voltage. Further, according to the input signal Vsw of the reference voltage switch terminal 100, the value of the reference voltage to be generated is changed between V2a and V2b.

With this structure, it is possible to apply substrate voltage Vsub higher than the high-level substrate voltage Vsub applied in the normal charge transfer period, as necessary. By reducing the amount of charge signal, it is possible to easily perform switching according to different driving modes for different number of pixels to be mixed, while maintaining optimum dynamic range for individual chip.

For example, the second reference voltage generating circuit 51 generates reference voltage V2b in a high-sensitivity mode for a still picture with nine-pixel mixture, and generates reference voltage V2a in a high-frame rate mode for moving image with six-pixel mixture. The reference voltage V2b is higher than the reference voltage V2a. Accordingly, it is possible to easily achieve a digital camera which can change driving mode, such as changing from the high-sensitivity mode for a still picture with nine-pixel mixture to the high-frame rate mode for moving image with six-pixel mixture.

The switch circuit 13 selectively switches the terminal 15 to which the shutter pulse SP is supplied and the terminal 16 to which the control pulse CON is supplied, for connecting to the terminal 14 connected to the capacitor 12. The drive circuit 8 outputs the control pulse CON in a state where the switch circuit 13 connects the terminal 14 to the terminal 16.

Accordingly, one of the shutter pulse SP and the control pulse CON is superimposed onto the reference voltage and applied, as the substrate voltage Vsub, to the n-type substrate 70 via the capacitor 12.

Note that the present embodiment is characterized in that the photodiodes 1, the vertical CCDs 2, the imaging region 3, the horizontal CCD 4, the charge detecting unit 5, the output amplifier 6, the first reference voltage generating circuit 50, and the second reference voltage generating circuit 51 are provided on a single semiconductor substrate chip made of the n-type substrate 70.

With such a structure, it is possible to achieve reduction in size and power consumption of the imaging device.

However, if providing the second reference voltage generating circuit 51 and the solid-state imaging element 7 on a single chip causes variability in properties, such as dark current of the solid-state imaging element 7, derived from heat distribution of the semiconductor substrate chip due to heat generated by the second reference voltage generating circuit 51, the second reference voltage generating circuit 51 may be provided as an external circuit.

Even in the case where the second reference voltage generating circuit 51 is provided as an external circuit, it is possible to apply the substrate voltage Vsub higher than the high-level substrate voltage Vsub applied in the normal charge transfer period; and thus, the amount of the charge signal can be reduced.

The above stated selection made by the switch circuit 13 can be switched by the mode selection signal Sm supplied according to the selection made by the driving mode selection unit which is now shown in the drawing.

The control pulse CON is superimposed onto the reference voltage supplied from the first reference voltage generating circuit 50 and applied to the n-type substrate 70 when the driving mode is in the pixel mixture mode.

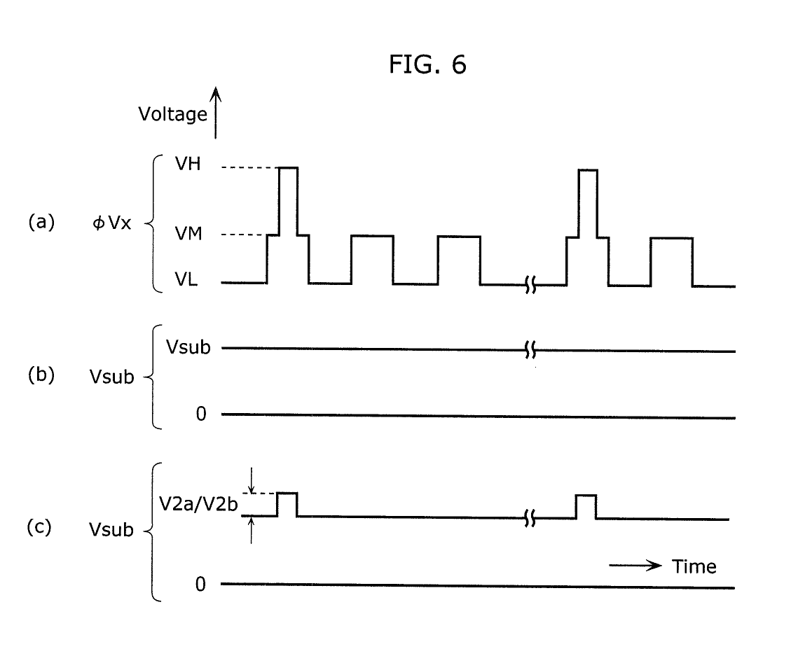

FIG. 6 shows an example of driving pulses according to the present embodiment.

The clock pulse φVx shown in FIG. 6(a) is applied to the electrode 18 which serves as a transfer electrode of the vertical CCD 2 and also as an electrode which controls transfer of signal charge from the photodiode 1.

The low-level voltage VL and the middle-level voltage VM in the clock pulse φVx are alternately applied so that the charge in the vertical CCD 2 is transferred.

The period during which the high-level voltage VH is applied is the charge transfer period.

This is the same as conventional methods.

FIG. 6 (b) shows the substrate voltage Vsub applied to the n-type substrate 70 in the all-pixel mode. The substrate voltage Vsub corresponds to the reference voltage supplied from the first reference voltage generating circuit 50, and takes a constant value throughout the charge accumulation period and the charge transfer period.

The shutter pulse SP supplied from the drive circuit 8 via the switch circuit 13 is not shown in the drawing for simplification.

The substrate voltage Vsub corresponds to the threshold at which excess charge is drained, that is, the potential 26a which defines the amount of the saturation charge shown in FIG. 5.

More specifically, when the substrate voltage Vsub is applied to the n-type substrate 70, the potential barrier (overflow barrier) in the p well region 17 is set to the potential 26a.

As described, in the all-pixel mode, the amount of saturation charge is determined by the low potential 26a, shown in FIG. 5, which takes a constant value throughout the charge accumulation period and the charge transfer period.

FIG. 6(c) shows the substrate voltage Vsub applied to the n-type substrate 70 in the pixel mixture mode.

The voltage V2a/V2b superimposed onto the substrate voltage Vsub corresponds to the control pulse CON supplied from the drive circuit 8.

More specifically, the substrate voltage has such a waveform that the control pulse CON whose crest value is determined by the voltage V2a/V2b supplied from the second reference voltage generating circuit 51 is superimposed onto the reference voltage Vsub supplied from the first reference voltage generating circuit 50.

The substrate voltage Vsub becomes high-level voltage Vsub+V2a or Vsub+V2b in the charge transfer period of the clock pulse φVx, and becomes low-level voltage Vsub in other periods.

The voltage Vsub+V2a or Vsub+V2b corresponds to the overflow barrier which defines the amount of the saturation charge indicated by the dashed line in FIG. 5.

As described, the amount of the saturation charge in the case of the pixel mixture is set to be larger in the charge accumulation period, and smaller in the charge transfer period.

As a result, during the charge accumulation period, it is possible to accumulate charge without losing spectral properties, sensitivity, and linearity by taking advantage of charge accumulation capability specific to the photodiodes 1.

Further, in the charge transfer period, unnecessary charge is drained so as to reduce the amount of charge for transferring. This prevents constraints in applicable voltage from being imposed, which provides favorable driving by pixel mixture.

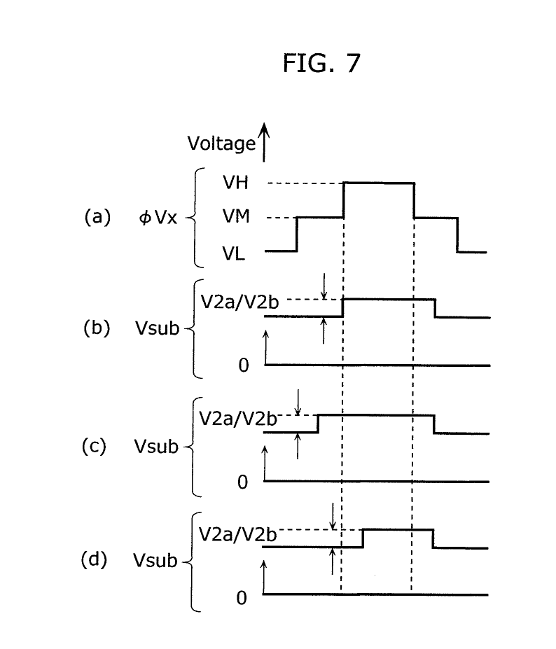

Next, the phase relationship between the clock pulse φVx in FIG. 6(a) and the control pulse CON superimposed onto the substrate voltage Vsub in FIG. 6(c) is described with reference to FIG. 7.

FIG. 7(a) and (b) schematically show enlarged pulse periods of the clock pulse φVx in FIG. 6(a) and of the substrate voltage Vsub in FIG. 6(c), respectively.

Further, FIG. 7(c) and (d) show variations of FIG. 7(b).

The high level period of the substrate voltage Vsub shown in FIG. 7(b) has a period overlapping with the high-level voltage VH period of the clock pulse φVx in FIG. 7(a).

More specifically, low-level substrate voltage Vsub, which is the same as in the conventional methods, is applied during most of the signal charge accumulation period, and high-level voltage is applied during the transfer period.

As a result, charge of the potential shallower (lower) than the potential 26b of FIG. 5 at which the excess charge is drained, is drained to the n-type substrate 70 without being accumulated in the photodiode 1.

Preferably, the rising edge of the high-level voltage is in phase with the rising edge of the high-level voltage of the clock pulse φVx in FIG. 7(a), that is, in phase with the start of the transfer period.

However, this slightly decreases draining of excess charge, which results in reducing controllability of the amount of signal.

Even though the controllability of the amount of signal is further decreased, the rising edge of the high-level voltage may be slightly delayed as shown in FIG. 7(d).

Further, as shown in FIG. 7(c), when high-level voltage is applied to the n-type substrate 70 before the transfer period, signal charge accumulated in the photodiode 1 is drained up to the potential 26b shown in FIG. 5; and thus, dynamic range of the photodiode 1 decreases, but controllability of the amount of signal is improved.

The falling edge of high-level voltage applied to the n-type substrate 70 may be in phase with the end of the transfer period. However, in view of simplification of synchronous control, slight delay as shown in FIG. 7(b) to (d) is preferable.

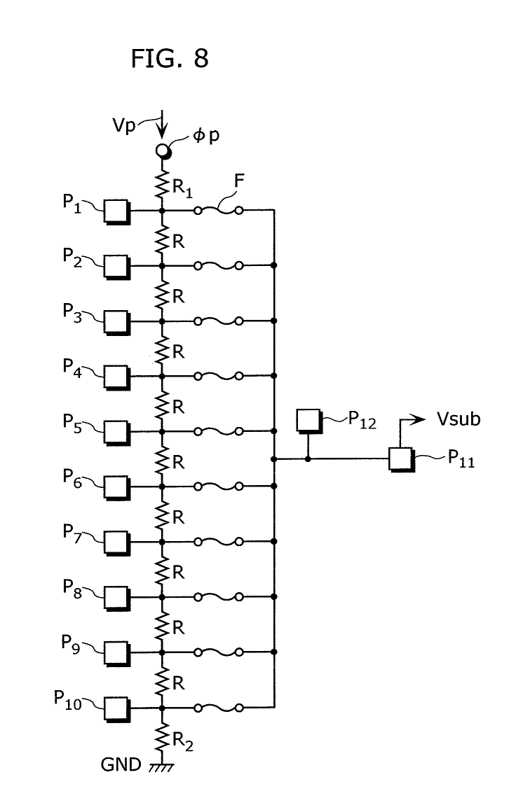

The first reference voltage generating circuit 50 may be structured as shown in the example of FIG. 8.

The circuit is a resistive dividing circuit in which a plurality of resistive elements are connected in series between power supply voltage Vp and ground (GND).

Pads P1 to P10 are respectively arranged at the connection points of the resistive elements R, R1 and R2.

Each connection point is further connected, via associated fuse F, to pad P11 which is for supplying reference voltage.

Further, a common pad P12 is connected to a wire which connects each fuse and the pad P11.

Each fuse F is blown by applying current between associated pad P1 to P10 and the common pad P12.

By selectively blowing unnecessary fuse F, a predetermined voltage is generated, and the generated voltage is supplied from the pad P11. As a result, manufacturing variability of individual chip can be compensated in the chip testing process, allowing setting of the optimum reference voltage.

Further, in the present embodiment, the example in which the charge drain region has a p well structure has been described; however, the present invention is not limited to this, but can be any charge drain region as long as it has a function to drain excess charge from photodiode.

For example, the so-called “overflow drain structure”, in which an overflow control gate and an overflow drain are provided adjacent to the photodiode, can also provide the similar advantageous effects by applying control pulse to the overflow control gate.

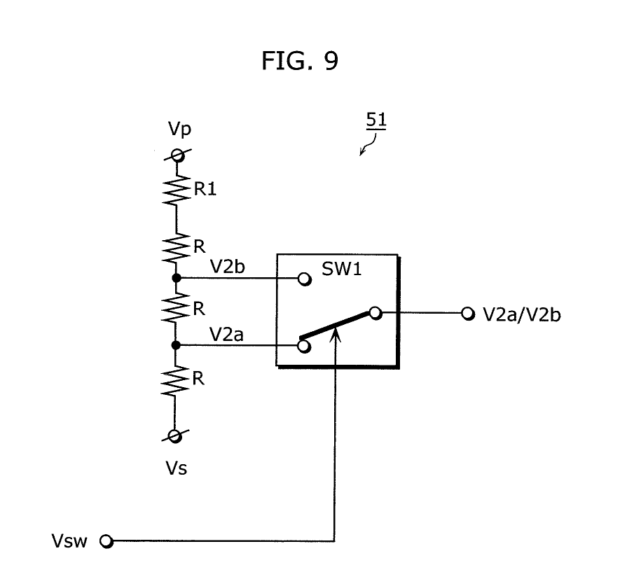

Further, the second reference voltage generating circuit 51 can be structured as an example shown in FIG. 9. In FIG. 9, the second reference voltage generating circuit 51 includes a resistive circuit and a switch circuit SW1. The resistive circuit includes a resistive element R1 and three resistive elements R that are connected in series, and outputs the first voltage V2a and the second voltage V2b by voltage division. The switch circuit SW1 includes an input terminal into which the switch signal Vsw indicating the first voltage V2a or the second voltage V2b is inputted, and switches, according to the switch signal Vsw, the output of the second reference voltage generating circuit 51 between the first voltage V2a and the second voltage Vsb.

With this, the second reference voltage generating circuit 51 can be simply configured, and switched according to the switch signal.

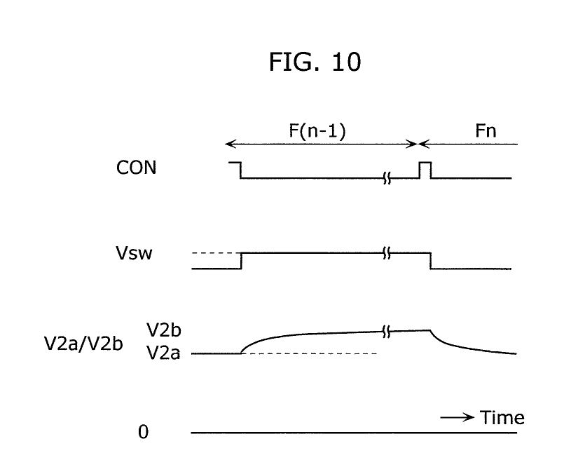

Further, it is preferable that the switch signal Vsw is supplied from the reference voltage switch terminal 100 immediately after the high-level voltage V2a/Vsb of the substrate voltage Vsub is applied (that is, immediately after the control pulse CON is applied) as shown in FIG. 10. Although high speed voltage switching is possible by the output transistor 103, drive capability of the output transistor 103 may be decreased due to problems associated with power consumption and generated heat. Therefore, by switching the switch signal Vsw from the reference voltage switch terminal 100 immediately after the high-level voltage 21b is applied as shown in FIG. 10, the transition period of the output signal voltage 111 of the second reference voltage generating circuit 51 can be made at maximum, thereby supplying constant high-level voltage V2a/V2b to the drive circuit 8.

As described, with the solid-state imaging device and drive method thereof according to an aspect of the present invention, it is possible to apply substrate voltage Vsub higher than the high-level substrate voltage Vsub applied in the normal charge transfer period according to the number of pixels to be mixed in the pixel mixture mode. By reducing the amount of charge signal depending on the number of pixels to be mixed, it is possible to mix pixel signals while maintaining optimum dynamic range for individual chip.

For example, the case where six and nine pixels are mixed is described in the present embodiment; however, it may be that pixels more than twelve or eighteen are mixed. Also, the example where the number of pixels to be mixed is switched between six and nine has been described, however, switching between six, nine, and twelve pixels is also be possible.

As described above, in the solid-state imaging device according to an embodiment of the present invention, it is possible to make, in the pixel mixture mode, the reference voltage have a waveform that control pulse supplied from the drive circuit is superimposed onto the voltage generated by the first reference voltage generating circuit.

Hereinafter, various variations of the solid-state imaging device according to the first embodiment are described.

It is preferable that the reference voltage in the pixel mixture mode is made to be a waveform that the voltage supplied from the first reference voltage generating circuit and control pulse supplied from the drive circuit upon reception of signal output of the second reference voltage generating circuit including reference voltage switch terminals are superimposed, and high level voltages are switched by voltage applied to the reference voltage switch terminal.

It is preferable that the rising edge of the high-level voltage be set so as to be in phase with the start of the charge transfer period in the pixel mixture mode, or to be delayed.

It is preferable that the falling edge of the high-level voltage be set so as to be in phase with the end of the charge transfer period in the pixel mixture mode, or to be delayed.

In the solid-state imaging device according to an aspect of the present invention, it is preferable that the second reference voltage generating circuit includes a constant current source and an output transistor.

It is preferable to perform switching by the reference voltage switch terminal according to an aspect of the present invention, immediately after the application of the high level voltage apply in the charge transfer period is changed to the low-level voltage apply.

The excess charge drain region may be a semiconductor substrate including the photoelectric conversion unit and the transfer unit.

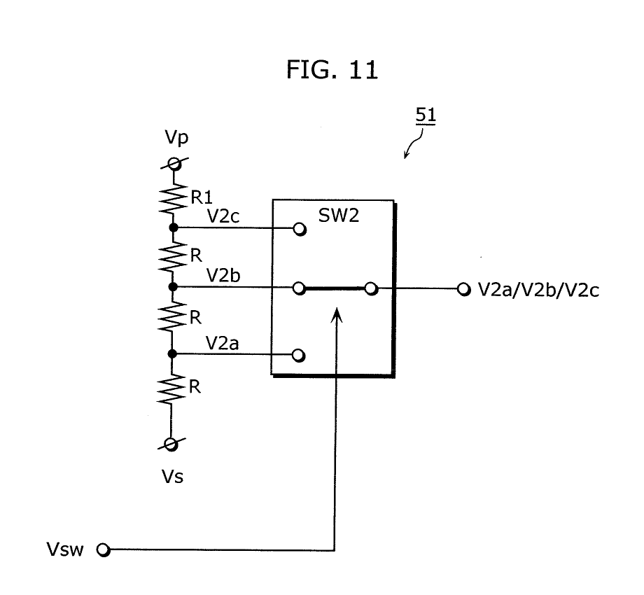

The second reference voltage generating circuit 51 may have any configurations shown in FIGS. 11 to 15 instead of that of FIG. 9.

FIG. 11 is a diagram showing a structure of the second reference voltage generating circuit 51 according to a first variation. The second reference voltage generating circuit 51 of FIG. 11 differs from that of FIG. 7 in that the switch circuit SW2 is included instead of the switch circuit SW1 and the output voltage from the resistive circuit is extended to three values. The switch circuit SW2 includes an input terminal to which a switch signal Vsw is inputted, and switches the output of the second reference voltage generating circuit 51 to any of the first voltage V2a, the second voltage Vsb, and the third voltage V2c, according to the switch signal Vsw. The first voltage to the third voltage can be expressed by V2a<Vsb<V2c. The third voltage is suitable for the third mixing mode in which signal charges of L photoelectric conversion elements (where M<L) are mixed that is a mode in which more signal charges are mixed compared to the second mixing mode.

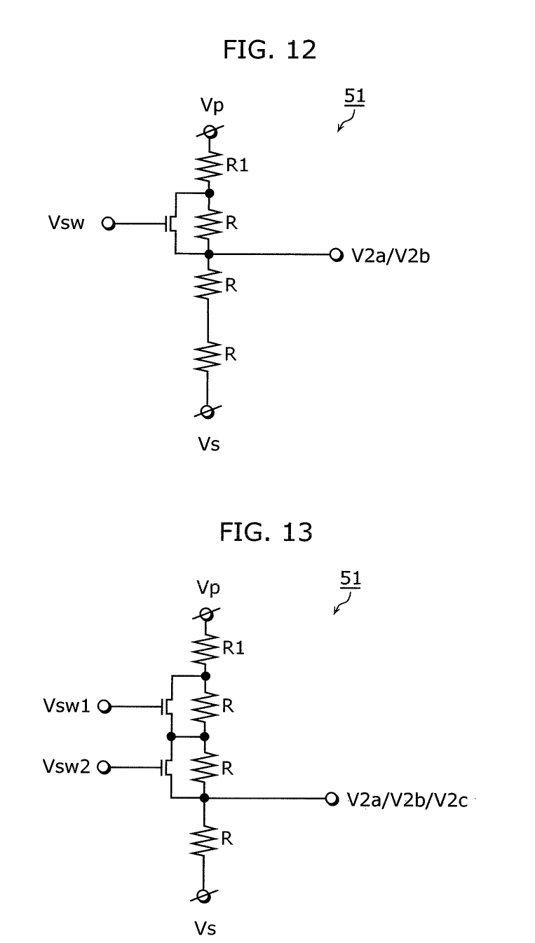

FIG. 12 is a diagram showing a structure of the second reference voltage generating circuit 51 according to a second variation. The second reference voltage generating circuit 51 of FIG. 12 differs from that of FIG. 7 in that a transistor switch is included instead of the switch circuit SW1. The switch transistor is connected in parallel with a resistive element among the plurality of resistive elements. The gate of the switch transistor is connected to the switch signal Vsw.

With this, a simple circuit structure is possible in which the switch transistor controls whether the resistive element is short circuited or not.

FIG. 13 is a diagram showing a structure of the second reference voltage generating circuit 51 according to a third variation. The second reference voltage generating circuit 51 of FIG. 13 differs from that of FIG. 12 in that an additional transistor switch is included. With this, according to combination of ON and OFF of two transistor switches, the output of the second reference voltage generating circuit 51 can be switched to any of the first voltage V2a, the second voltage Vsb, and the third voltage V2c.

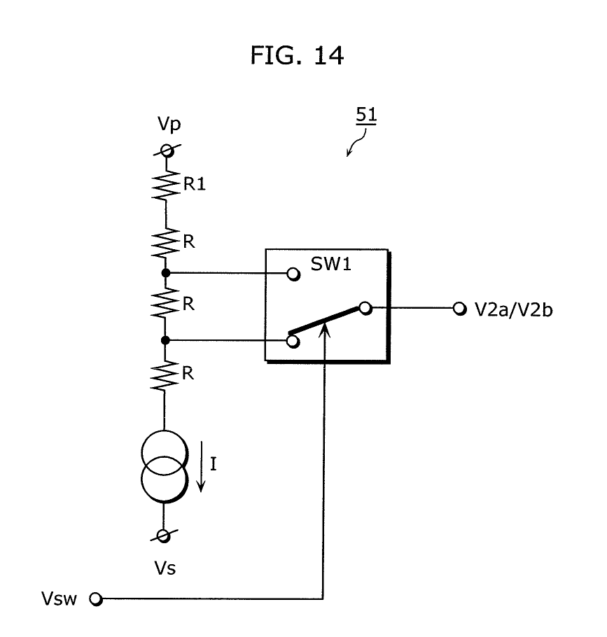

FIG. 14 is a diagram showing a structure of the second reference voltage generating circuit 51 according to a fourth variation. The second reference voltage generating circuit 51 of FIG. 14 differs from that of FIG. 9 in that a constant current source is added. Compared to FIG. 9, in the second reference voltage generating circuit 51 of FIG. 14, voltage drop of the resistive elements can be considered as constant regardless of load of the output side; and thus, it is possible to improve the accuracy of the first and second voltages V2a and V2b.

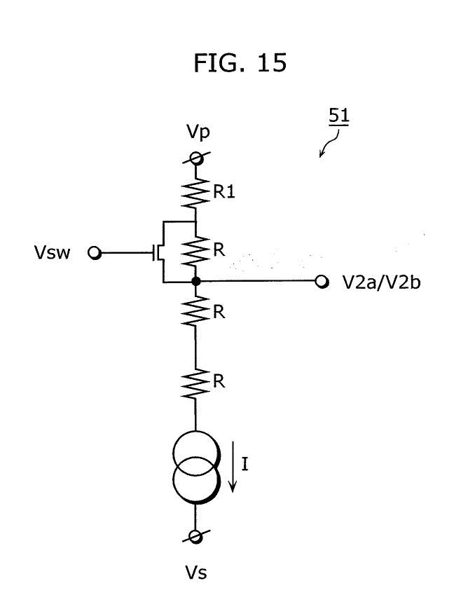

FIG. 15 is a diagram showing a structure of the second reference voltage generating circuit 51 according to a fifth variation. The second reference voltage generating circuit 51 of FIG. 15 differs from that of FIG. 12 in that a constant current source is added. The second reference voltage generating circuit 51 of FIG. 15 can improve accuracy of the first and second voltages V2a and V2b, as in the second reference voltage generating circuit 51 of FIG. 14.

### Second Embodiment

The solid-state imaging device according to the second embodiment is described which has a function to compensate the adverse effects of manufacturing variability for each solid-state imaging element in addition to the functions of the solid-state imaging device according to the first embodiment.

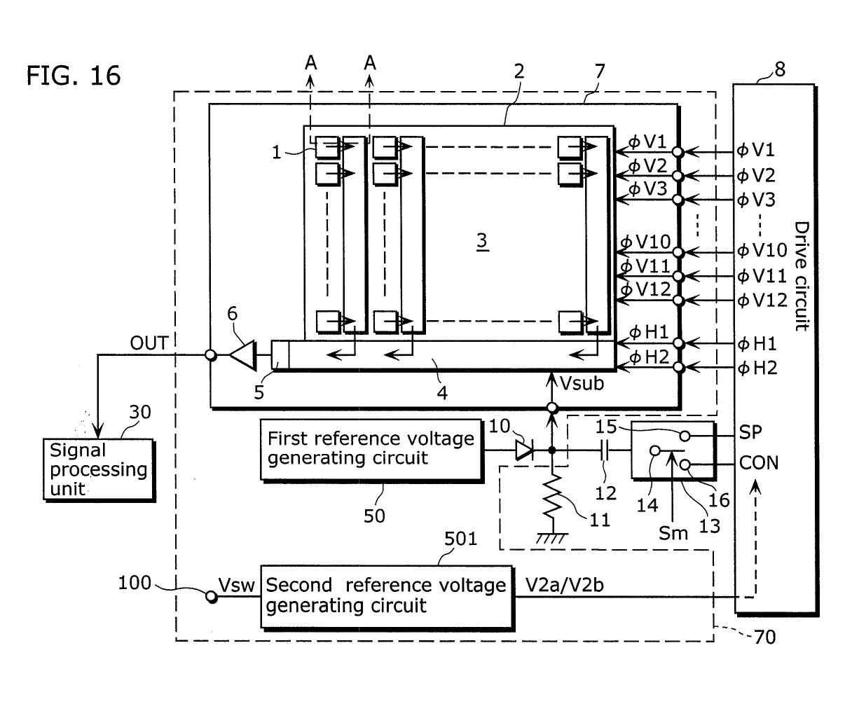

FIG. 16 is a block diagram showing a structure of the solid-state imaging device according to the second embodiment of the present invention. The structure shown in FIG. 16 differs from that in FIG. 3 in that a second reference voltage generating circuit 501 is included instead of the second reference voltage generating circuit 51. Since the elements with the same reference numerals have same functions, descriptions thereof are not repeated. Hereinafter, only differences are mainly described.

Compared to the second reference voltage generating circuit 51, a trimming mechanism for fine control of the output voltage V2a/V2b is added in the second reference voltage generating circuit 501.

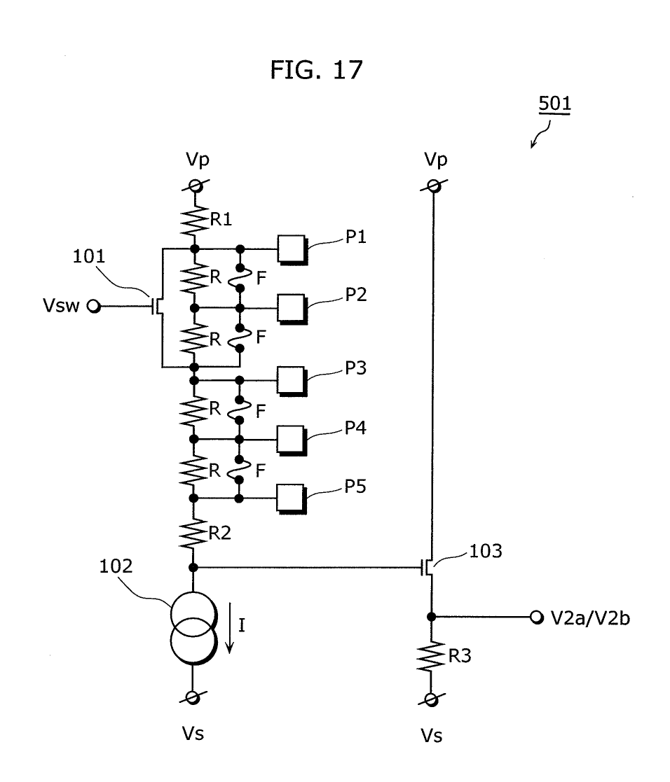

FIG. 17 is a diagram showing an example of the second reference voltage generating circuit 501.

The second reference voltage generating circuit 501 includes, between the input terminals Vp and Vs, a resistive dividing circuit in which resistive elements are connected in series, a switch transistor (hereinafter, referred to as SW_Tr) 101, a constant current source 102 and an output transistor 103. Power source voltage is supplied from the input terminals Vp and Vs, and voltage V2a/V2b outputted to the output terminal can be switched according to the signal voltage applied to the input terminal Vsw.

Pads P1 to P5 are respectively arranged at the connection points of the resistive elements R, R1 and R2.

Each fuse F is blown by applying current between associated pads P1 to P5.

By selectively blowing unnecessary fuse F, desired voltage is generated in the gate of the output transistor 103 with the current I determined by the constant current source 102 and voltage drop of the resistive elements R, R1 and R2. Then, output signal voltage of the second reference voltage generating circuit 51 is outputted from the output terminal Vout after the output transistor 103 performing impedance conversion into the low impedance. The conversion into the low impedance allows high-speed voltage switching. When the SW_Tr 101 is turned ON by the signal voltage of the input terminal φsw, the voltage drop of the resistive element R connected in parallel with the SW_Tr 101 becomes combined resistive element with the ON resistive element of the SW_Tr 101 and becomes extremely low. As a result, the signal voltage of the output terminal (pout increases.

For example, in the case of mixing nine pixels, it can be set such that SW_Tr 101 is turned ON, and the signal voltage of the output terminal Vout is increased by voltage drop of the two resistive elements R and resistive elements R1 and R2. In the case of mixing six pixels, it can be set such that the SW_Tr 101 is turned OFF, and the signal voltage of the output terminal (pout is decreased by voltage drop of the four resistive elements R and resistive elements R1 and R2.

With this, it is possible to set optimum reference voltage according to the number of pixels to be mixed while compensating manufacturing variability for each chip through selection of fuse F. Furthermore, by including the constant current source 102, selection of fuse F can be made independently among modes with different number of pixels to be mixed. This facilitates the selection of fuse F, and the shortened selection time allows reduction in chip testing time.

Further, since the constant current source is included, voltage drop of the resistive elements can be considered constant regardless of load of the output side. Thus, it is possible to improve accuracy of the first and second voltages V2a and V2b.

Hereinafter, various variations of the solid-state imaging device according to the first embodiment are described.

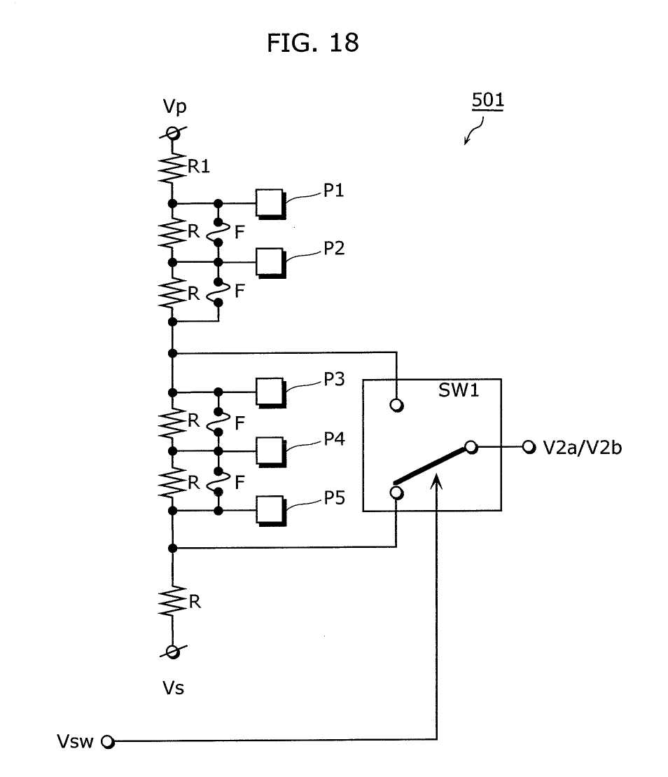

The second reference voltage generating circuit 501 may have any configurations shown in FIGS. 18 to 27 instead of that of FIG. 17.

FIG. 18 is a diagram showing a structure of the second reference voltage generating circuit 501 according to a first variation. The second reference voltage generating circuit 501 of FIG. 18 differs from that of FIG. 17 in that the output transistor 103 is deleted, a resistive element is included instead of the constant current source, and the switch circuit SW1 is included instead of the transistor switch. The second reference voltage generating circuit 501 in FIG. 18 can have a simpler structure compared to that of FIG. 17.

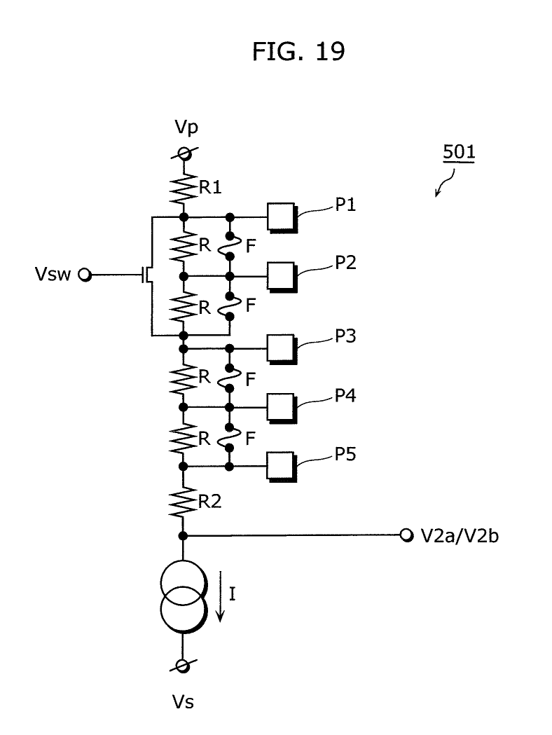

FIG. 19 is a diagram showing a structure of the second reference voltage generating circuit 501 according to a second variation. The second reference voltage generating circuit 501 of FIG. 19 differs from that of FIG. 18 in that a constant current source is included instead of one of the resistive elements, and a switch transistor is included instead of the switch circuit SW1. By including the constant current source, it is possible to improve accuracy of the output voltage.

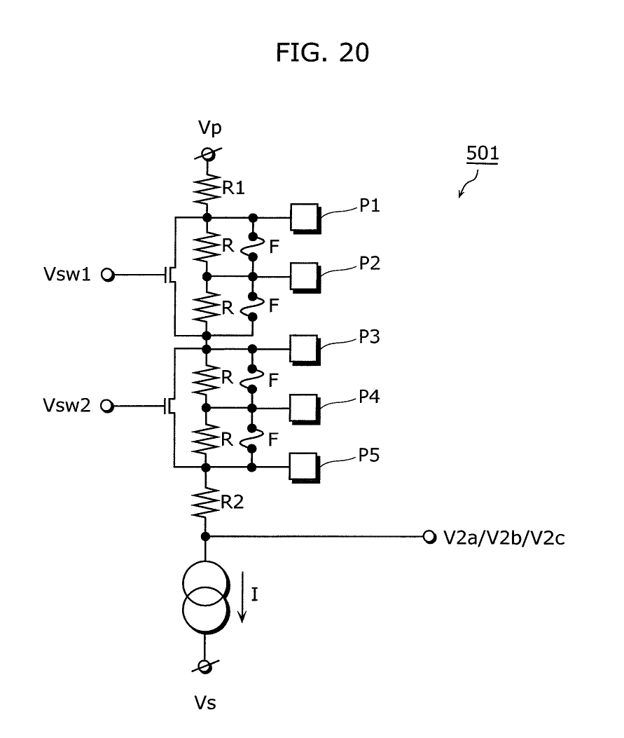

FIG. 20 is a diagram showing a structure of the second reference voltage generating circuit 501 according to a third variation. The second reference voltage generating circuit 501 of FIG. 20 differs from that of FIG. 19 in that an additional transistor switch is included. This allows selective output of the first to third voltage V2a/V2b/V2c.

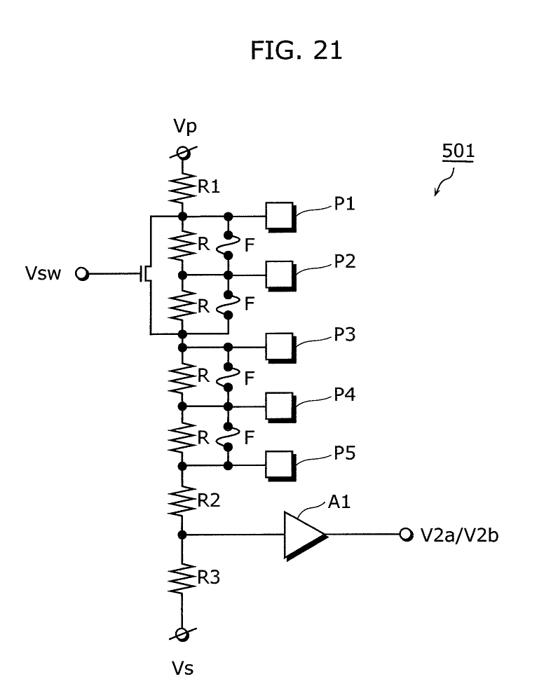

FIG. 21 is a diagram showing a structure of the second reference voltage generating circuit 501 according to a fourth variation. The second reference voltage generating circuit 501 of FIG. 21 differs from that of FIG. 19 in that a resistive element is included instead of the constant current source and a voltage buffer circuit A1 is added. This structure allows the voltage buffer circuit A1 to increase the level of the output from the second voltage generating circuit to the steady level of the first voltage or the second voltage more rapidly. As a result, high-speed switching of the substrate voltage is possible. Further, since the output impedance seen from the resistive circuit is converted by the voltage buffer circuit A1, it is possible to improve accuracy of the output voltage even by the resistive division only.

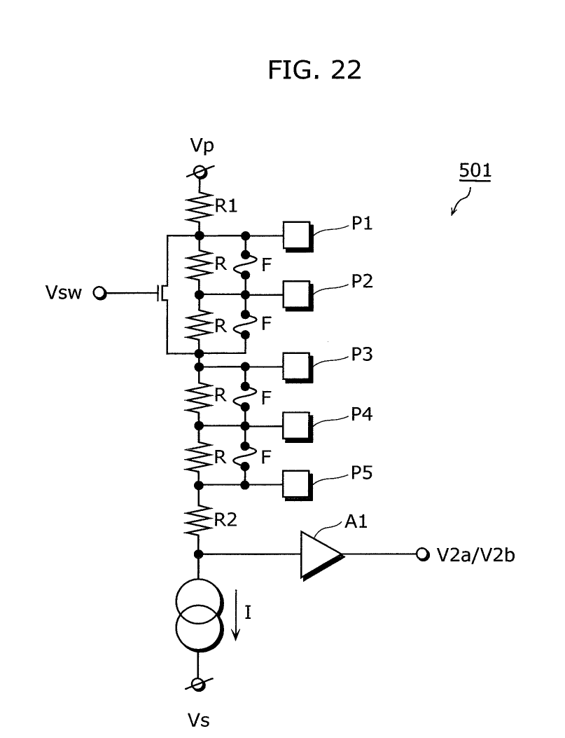

FIG. 22 is a diagram showing a structure of the second reference voltage generating circuit 501 according to a fifth variation. The second reference voltage generating circuit 501 of FIG. 22 differs from that of FIG. 21 in that a current source is included instead of one of the resistive elements.

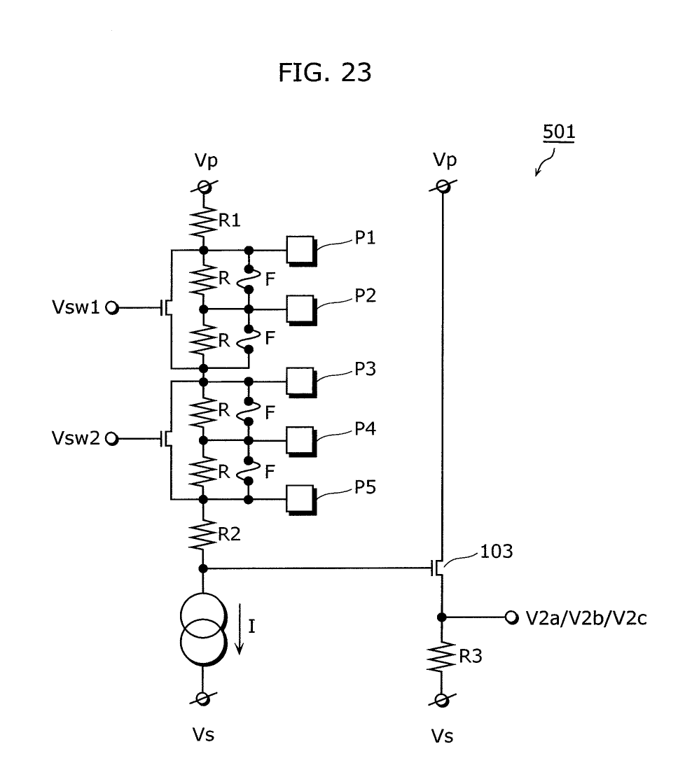

FIG. 23 is a diagram showing a structure of the second reference voltage generating circuit 501 according to a sixth variation. The second reference voltage generating circuit 501 of FIG. 23 differs from that of FIG. 17 in that an additional transistor switch is included. This allows selective output of the first to third voltages V2a/V2b/V2c.

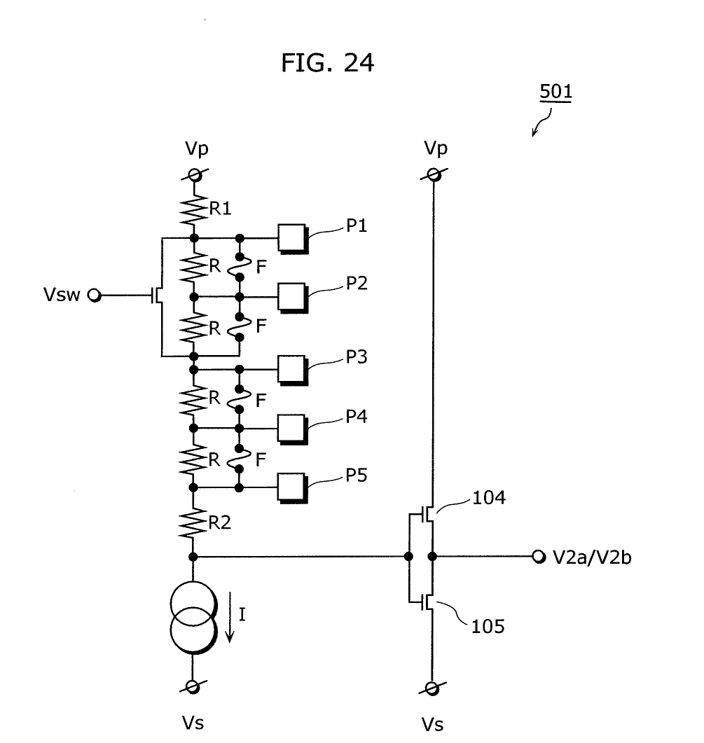

FIG. 24 is a diagram showing a structure of the second reference voltage generating circuit 501 according to a seventh variation. The second reference voltage generating circuit 501 of FIG. 24 differs from that of FIG. 17 in that a pair of push-pull transistors are added instead of the output transistor 103 and the resistive element R3 constituting a source follower. The pair of the push-pull transistors can reduce power consumption more than the source follower.

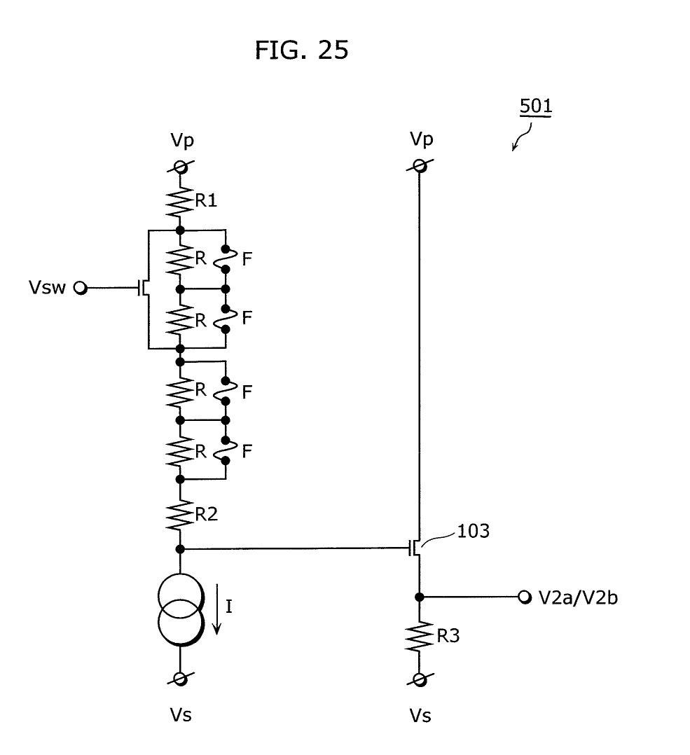

FIG. 25 is a diagram showing a structure of the second reference voltage generating circuit 501 according to an eighth variation. The second reference voltage generating circuit 501 of FIG. 25 differs from that of FIG. 17 in that pads P1 to P5 are deleted. The fuses F of FIG. 25 differ from those of FIG. 17 in that they are not blown by current exceeding a threshold, but blown by laser. This allows reduction in circuit area for the area of the omitted pads P1 to P5. Note that for the second reference voltage generating circuit 501 in FIGS. 17 to 24, and FIG. 26 according to the second embodiment, fuses may be blown by laser similarly to FIG. 25.

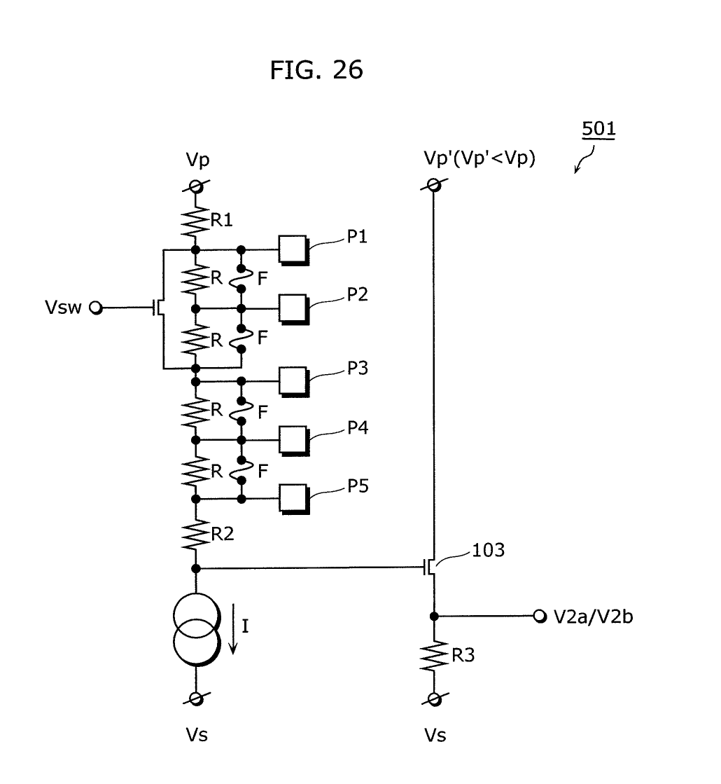

FIG. 26 is a diagram showing a structure of the second reference voltage generating circuit 501 according to a ninth variation. The second reference voltage generating circuit 501 of FIG. 26 differs from that of FIG. 17 in that the source follower (the transistor and the resistive element R3) is connected to the power source Vp′ which is different from the power source of the resistive circuit. The power source voltage can be expressed by Vp′<Vp. This allows improvement of reliability since power source voltage applied to the output transistor is low.

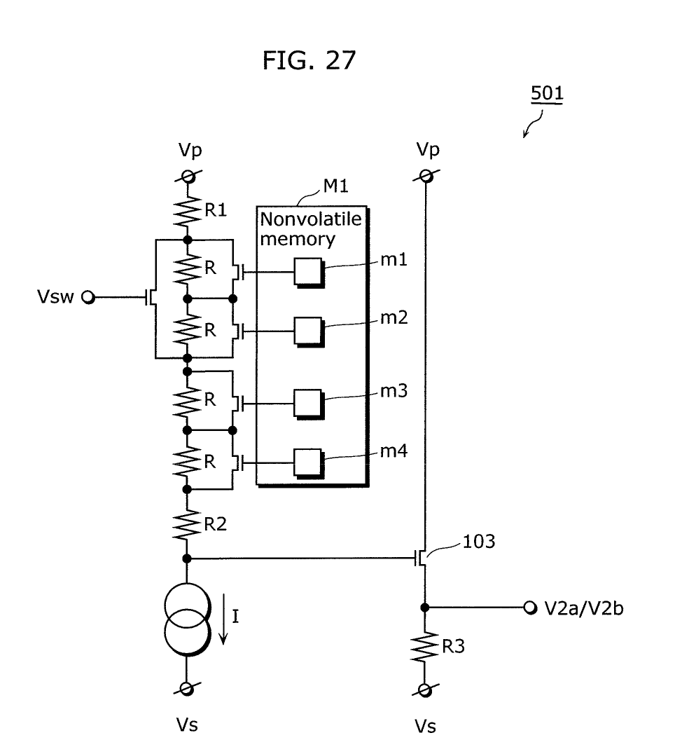

FIG. 27 is a diagram showing a structure of the second reference voltage generating circuit 501 according to a tenth variation. The second reference voltage generating circuit 501 of FIG. 27 differs from that of FIG. 17 in that transistors are included instead of fuses, and nonvolatile memory M1 is added.

Each switch transistor is turned ON and OFF according to the corresponding bits of the nonvolatile memory M1, and serves as a fuse.

The nonvolatile memory stores 4 bits m1 to m4. Each bit output line is connected to the gate of the associated transistor. The data of the 4 bits m1 to m 4 are written as trimming data by software, at the time of factory shipment.

This allows reduction in circuit area because pads are not required. In addition, since step of physically blowing fuses is implemented by software, production costs at the time of factory shipment can be reduced.

Note that for structures shown in FIG. 18 to FIG. 26, software trimming can be applied.

Further, the solid-state imaging devices according to the first and second embodiments are implemented for cameras such as camcorders and digital still cameras.

### INDUSTRIAL APPLICABILITY

The solid-state imaging device and drive method thereof according to an aspect of the present invention can accumulate charge without losing spectral properties, sensitivity and linearity in the charge accumulation period. By draining unnecessary charge and transferring reduced amount of charge in the charge transfer period, favorable driving in the pixel mixture mode is possible without constraints of applicable voltage. Thus, the solid-state imaging device and drive method thereof according to an aspect of the present invention are suitable for a camcorder, digital still camera, image sensor for medical endoscope, camera phone, security camera, camera integrated into laptop computer, camera unit connected to information processor and the like.

1. A solid-state imaging element formed on a semiconductor substrate, having an overflow drain structure for draining excess charges generated in photoelectric conversion elements, and reading out signal charges accumulated in the photoelectric conversion elements to a vertical transfer unit via a readout gate electrode, said solid-state imaging element comprising:
a first voltage generating circuit which applies a substrate voltage to the semiconductor substrate, the substrate voltage defining a height of an overflow barrier in the overflow drain structure; and
a second voltage generating circuit which selectively generates a first voltage and a second voltage at a time when a readout pulse to be applied to the readout gate electrode is generated, the first voltage and the second voltage each indicating a height of a pulse wave superimposed onto the substrate voltage.

2. The solid-state imaging element according to claim 1,
wherein said second voltage generating circuit:
generates the first voltage in a first mixing mode in which signal charges of N photoelectric conversion elements are mixed in the vertical transfer unit; and
generates the second voltage higher than the first voltage in a second mixing mode in which signal charges of M photoelectric conversion elements are mixed, M being greater than N.

3. The solid-state imaging element according to claim 2,
wherein said second voltage generating circuit includes:
a resistive circuit which includes resistive elements connected in series, and outputs the first voltage and the second voltage by a voltage division; and
a switch circuit which includes an input terminal to which a switch signal indicating the first voltage or the second voltage is inputted, and switches an output of said resistive circuit between the first voltage and the second voltage according to the switch signal.

4. The solid-state imaging element according to claim 3,
wherein the switch signal is switched immediately after the readout pulse is generated in a field period or a frame period, each of the field period and the frame period being a period immediately before switching into the first mixing mode or the second mixing mode.

5. The solid-state imaging element according to claim 3,
wherein said switch circuit includes a switch transistor which is connected in parallel with a first resistive element among said resistive elements, and
said switch transistor includes a gate connected to said input terminal.

6. The solid-state imaging element according to claim 3,
wherein said second voltage generating circuit further includes a constant current source connected in series with said resistive elements.

7. The solid-state imaging element according to claim 3,
wherein said second voltage generating circuit further includes a voltage buffer circuit which drives the first voltage or the second voltage outputted from said resistive circuit.

8. The solid-state imaging element according to claim 3,
wherein said switch circuit further includes at least one fuse circuit which is connected in parallel with a resistive element among said resistive elements.

9. The solid-state imaging element according to claim 8,
wherein said switch circuit further includes at least two pads which receive power for blowing said fuse circuit.

10. A solid-state imaging device formed on a semiconductor substrate, having an overflow drain structure for draining excess charges generated in photoelectric conversion elements, and reading out signal charges accumulated in the photoelectric conversion elements to a vertical transfer unit via a readout gate electrode, said solid-state imaging device comprising:
a first voltage generating circuit which applies a substrate voltage to the semiconductor substrate, the substrate voltage defining a height of an overflow barrier in the overflow drain structure;
a second voltage generating circuit which selectively generates a first voltage and a second voltage at a time when a readout pulse to be applied to the readout gate electrode is generated, the first voltage and the second voltage each indicating a height of a pulse wave superimposed onto the substrate voltage; and
a drive unit configured to drive the vertical transfer unit.

11. The solid-state imaging device according to claim 10,
wherein said drive unit is configured (i) to drive the photoelectric conversion elements and the vertical transfer unit such that signal charges of N photoelectric conversion elements are mixed in the vertical transfer unit in a first mixing mode, and (ii) to drive the photoelectric conversion elements and the vertical transfer unit such that signal charges of M photoelectric conversion elements are mixed in a second mixing mode, M being greater than N,
said second voltage generating circuit generates the first voltage in the first mixing mode, and generates the second voltage higher than the first voltage in the second mixing mode, and
said drive unit is configured: (i) to superimpose, in the first mixing mode, a pulse of the first voltage onto the substrate voltage at a time when the readout pulse is generated, and (ii) to superimpose, in the second mixing mode, a pulse of the second voltage onto the substrate voltage at a time when the readout pulse is generated.

12. The solid-state imaging device according to claim 11,
wherein said second voltage generating circuit includes:
a resistive circuit which includes resistive elements connected in series, and outputs the first voltage and the second voltage by a voltage division; and
a switch circuit which includes an input terminal to which a switch signal indicating the first voltage or the second voltage is inputted, and switches an output of said resistive circuit between the first voltage and the second voltage according to the switch signal.

13. The solid-state imaging device according to claim 12,
wherein the switch signal is switched immediately after the readout pulse is generated in a field period or a frame period, each of the field period and the frame period being a period immediately before switching into the first mixing mode or the second mixing mode.

14. The solid-state imaging device according to claim 11,
wherein said switch circuit includes a switch transistor which is connected in parallel with a first resistive element among said resistive elements, and
said switch transistor includes a gate connected to said input terminal.

15. The solid-state imaging device according to claim 12,
wherein said second voltage generating circuit further includes a constant current source connected in series with the resistive elements.

16. The solid-state imaging device according to claim 11,
wherein said second voltage generating circuit further includes a voltage buffer circuit which drives the first voltage or the second voltage outputted from said resistive circuit.

17. The solid-state imaging device according to claim 11,
wherein said switch circuit further includes at least one fuse circuit which is connected in parallel with a resistive element among said resistive elements.

18. The solid-state imaging device according to claim 17,
wherein said switch circuit further includes at least two pads which receive power for blowing said fuse circuit.

19. A camera comprising the solid-state imaging device according to claim 10.

20. A drive method of a solid-state imaging device formed on a semiconductor substrate, having an overflow drain structure for draining excessive charges generated in photoelectric conversion elements, and reading out signal charges accumulated in the photoelectric conversion elements to a vertical transfer unit via a readout gate electrode, said drive method comprising:
applying a substrate voltage to the semiconductor substrate, the substrate voltage defining a height of an overflow barrier in the overflow drain structure; and
superimposing the substrate voltage onto a pulse of a first voltage at a time when a readout pulse to be applied to the readout gate electrode is generated, in a first mixing mode in which the vertical transfer unit mixes signal charges of N photoelectric conversion elements, and
superimposing the substrate voltage onto a pulse of a second voltage higher than the first voltage at a time when the readout pulse is generated, in a second mixing mode in which the vertical transfer unit mixes signal charges of M photoelectric conversion elements, M being greater than N.
